(19) United States
(12) Patent Application Publication
(10) Pub. No.: US 2022/0181594 A1
(43) Pub. Date: Jun. 9, 2022

(54) METHOD FOR MANUFACTURING RESIN FILM HAVING FINE PATTERN, METHOD FOR MANUFACTURING ORGANIC EL DISPLAY DEVICE, BASE MATERIAL FILM FOR USE IN FORMATION OF FINE PATTERN, AND RESIN FILM HAVING SUPPORT MEMBER ATTACHED THERETO

(71) Applicant: SAKAI DISPLAY PRODUCTS CORPORATION, Sakai-shi, Osaka (JP)

(72) Inventors: KATSUHIKO KISHIMOTO, Sakai-shi, Osaka (JP); SUSUMU SAKIO, Sakai-shi, Osaka (JP)

(21) Appl. No.: 17/442,850

(22) PCT Filed: Mar. 27, 2019
(86) PCT No.: PCT/JP2019/013460

§ 371 Date: Nov. 23, 2021

(51) Int. Cl. H01L 51/56; C23C 14/04; H05B 33/10; H01L 51/00; H01L 27/32

(52) U.S. Cl. CPC H01L 51/56; C23C 14/042; H01L 27/3244; H01L 51/001; H05B 33/10

(57) ABSTRACT

A metal layer is formed on a first surface of a flat-plate-like support member, and then a resin cured layer is formed on the metal layer. The resin cured layer is irradiated with laser light for fine processing to form a desired fine pattern, thereby manufacturing a resin film having a fine pattern. Subsequently, ultraviolet light having a wavelength different from that of the laser light for fine processing is irradiated toward a second surface of the support member, which is opposed to the first surface to detach the resin film from the support member.

### TECHNICAL FIELD

The present disclosure relates to a method for manufacturing a resin film having a fine pattern, which method is to process and form the fine pattern, with a laser light, on a resin-made film and a method for manufacturing an organic electroluminescent (EL) display apparatus, and a base film for forming the above-mentioned fine pattern and a resin film with a supporting member.

### BACKGROUND ART

In a case that an organic EL display apparatus is manufactured, an organic layer is deposited on a substrate on which are formed TFTs, for example, the deposited organic layer corresponding to each of pixels. Therefore, a vapor deposition mask is arranged on the substrate, an organic material is deposited via the above-mentioned vapor deposition mask, and a necessary organic layer is deposited only at a necessary pixel location. As the vapor deposition mask, a metal mask has been used conventionally, but, in recent years, there is a tendency for a vapor deposition mask containing a resin film to be used often instead of the metal mask.

Such a vapor deposition mask containing the resin film is, as shown in Patent Document 1, for example, manufactured by forming, with a laser light, a fine pattern of the vapor deposition mask, which fine pattern includes an opening pattern, for example, in a resin film formed on a supporting member and then peeling off the above-mentioned resin film. In this case, air bubbles can be caught in the resin film being bonded to the supporting member, and, when a fine pattern such as an opening is formed in an air bubble portion, burrs and/or floating occurs at the end of the opening, so that an accurate fine pattern is not formed. Therefore, forming the resin film being in close contact with the supporting member by coating a liquid resin onto the supporting member to cure the liquid resin, and fine processing the formed resin film with a laser light is disclosed in Patent document 1, Moreover, Patent document 1 also discloses a method for forming an ultraviolet light absorbing layer at an interface between the resin film and the supporting member when the liquid resin is cured, and, after fine processing, irradiating an ultraviolet light to peel off the resin film from the supporting member.

Furthermore, a sheet made of a resin and a sheet made of a metal being laminated via a UV peeling layer formed of an acrylic-based UV repeeling-type adhesive, for example, the sheet made of the metal being etched to administer fine processing, and then a UV light being irradiated to peel off the sheet made of the metal therefrom and forming a metal mask are also known (see Patent document 2, for example).

Moreover, Patent document 3 discloses a method in which, in a case of manufacturing a flexible display, depositing, on a glass substrate, for example, a light-heat conversion layer formed of Molybdenum (Mo) and a sheet to be peeled off, which sheet to be peeled off is formed of polyimide, and, after forming of a device, irradiating a wide wavelength range light onto the light-heat conversion layer to peel off the layer to be peeled off and the glass substrate.

### PRIOR ART DOCUMENT

### Patent Documents

Patent document 1: WO2017/056656

Patent document 2: Japanese Patent Application Publication No. 2009-052072

Patent document 3: Japanese Patent Application Publication No. 2013-145808

### SUMMARY OF THE INVENTION

### Problem to be Solved by the Invention

As shown in Patent document 1, there is a danger that, when a fine pattern is formed by irradiating a laser light onto a supporting member with a resin film being formed thereon, which supporting member is formed of a glass plate, a stray light being a laser light having transmitted through the supporting member to be randomly reflected by an external work could return to the resin film, and again process the finely-processed portion to change the fine shape. Therefore, what is described above is not suitable for forming a very fine pattern.

Moreover, as shown in Patent document 1, when an ultraviolet ray absorbing layer is modified by irradiating thereon an ultraviolet light after fine processing, the resin film also absorbs the ultraviolet light, so that the temperature increases. As a result, the debris scraped off the resin film at the time of fine processing to scatter to be adhered to the surface of the resin film burs on the surface of the resin film, so that it can be difficult to remove the debris even with cleaning thereafter.

Furthermore, in Patent Document 2, there is a problem in peeling off the sheet made of the resin and the sheet made of the metal even when an acrylic-based UV repeeling-type adhesive to be cured by the ultraviolet light is formed at the interface thereof, which problem is similar to that disclosed in Patent Document 1 described previously.

Moreover, while Patent document 3 does not disclose administering fine processing, there is a problem that, since a deviation due to the difference in thermal expansion between the sheet made of a resin and the layer to undergo light-heat conversion, such as Mo, occurs due to light-heat conversion occurring at the time of fine processing, an accurate fine pattern cannot be formed.

The present disclosure is aimed at solving such problems, and, while accurately administering fine processing on a resin layer, easily peeling off a resin film on which the above-mentioned fine processing is administered without affecting a fine pattern.

### Means to Solve the Problem

A method for manufacturing a resin film having a fine pattern according to a first Embodiment of the present disclosure comprises: forming a metal layer on a first surface of a supporting member being a flat-plate (a flat-plate supporting) member; forming a resin cured layer by curing a liquid resin material being applied on a surface of the metal layer, which surface is opposite to the supporting member; forming a resin film having the fine pattern by forming a desired fine pattern on the resin cured layer with irradiation of a laser light for fine processing from a position opposing the resin cured layer; irradiating an ultraviolet light toward a second surface of the supporting member, which second surface is a surface opposite to the first surface, which ultraviolet light has a wavelength being different from a wavelength of the laser light for fine processing; and peeling off the resin film from the supporting member.

A method for manufacturing an organic EL display apparatus according to a second Embodiment of the present disclosure in which an organic layer is deposited on a substrate to manufacture the organic EL display apparatus, the method comprising: forming a vapor deposition mask with the previously-described method; aligning and superimposing the vapor deposition mask on a substrate with a first electrode, and depositing the organic layer on the substrate by vapor-depositing an organic material; and removing the vapor deposition mask, and forming a second electrode.

A base film for forming a fine pattern according to a third Embodiment of the present disclosure, in which base film, the fine pattern is to be formed by laser processing, the base film comprising: a supporting member being a flat-plate; a metal layer formed on a first surface of the supporting member; and a resin cured layer formed on a surface of the metal layer, which surface is opposite to the supporting member, wherein the metal layer has a reflectance being greater than or equal to 40% with respect to a light having a wavelength of a visible light or any wavelength of an ultraviolet light and an absorptance being greater than or equal to 50% with respect to a light having any wavelength of an ultraviolet light.

A resin film with a supporting member according to a fourth Embodiment of the present disclosure comprises: a supporting member being a flat-plate; a metal layer formed on a first surface of the supporting member; and a resin film having a fine pattern, which resin film is formed on a surface of the metal layer, which surface is opposite to the supporting member, wherein the metal layer has a reflectance being greater than or equal to 40% with respect to a fight having a wavelength of a visible light or any wavelength of an ultraviolet light and an absorptance being greater than or equal to 50% with respect to a light having any wavelength of an ultraviolet light.

### Effects of the Invention

According to the present disclosure, in a case that fine processing is administered, with a laser light, on a resin cured film formed on one surface of a supporting member, the laser light is caused to be reflected by a metal layer on a rear surface of the resin cured layer. Therefore, a stray light can be reduced significantly, which stray light is a laser light having transmitted through the resin film exiting the supporting member to be reflected by various reflecting surfaces such as a stage to return to the resin film. On the other hand, when a resin film on which fine processing is administered is peeled off from the supporting member, irradiating an ultraviolet light having a wavelength different from that of the laser light for fine processing causes the metal layer, for example, to generate heat. As a result, the interface between the resin film and the metal layer can be separated, making it possible to easily peel off the resin film from the supporting member.

### BRIEF DESCRIPTION OF THE DRAWINGS

FIG. 1 is a flowchart showing a method for manufacturing a resin film according to a first Embodiment of the present disclosure.

FIG. 2A is a cross-sectional view of one step of the method for manufacturing of FIG. 1.

FIG. 2B is a cross-sectional view of one step of the method for manufacturing of FIG. 1.

FIG. 2C is a cross-sectional view of one step of the method for manufacturing of FIG. 1.

FIG. 2D is a cross-sectional view of one step of the method for manufacturing of FIG. 1,

FIG. 2E is a cross-sectional view of one step of the method for manufacturing of FIG. 1,

FIG. 3A is a reflection characteristic of silver (Ag) with respect to the wavelength.

FIG. 3B is an absorption characteristic of silver (Ag) with respect to the wavelength.

FIG. 4A is a reflection characteristic of gold (Au) with respect to the wavelength.

FIG. 4B is an absorption characteristic of gold (Au) with respect to the wavelength.

FIG. 5A is a reflection characteristic of copper (Cu) with respect to the wavelength.

FIG. 5B is an absorption characteristic of copper (Cu) with respect to the wavelength.

FIG. 6A is a reflection characteristic of nickel (Ni) with respect to the wavelength.

FIG. 6B is an absorption characteristic of nickel (Ni) with respect to the wavelength.

FIG. 7A is a reflection characteristic of Molybdenum (Mo) with respect to the wavelength.

FIG. 7B is an absorption characteristic of Molybdenum (Mo) with respect to the wavelength.

FIG. 8A is a reflection characteristic of aluminum (Al) with respect to the wavelength.

FIG. 8B is an absorption characteristic of aluminum (Al) with respect to the wavelength.

FIG. 9 is a view illustrating one example of forming a resin coating layer of FIG. 2B.

FIG. 10A is an illustrative view at the time of forming an opening in a vapor deposition mask with irradiation of a laser light.

FIG. 10B is an illustrative view of the state of the laser light being refracted by an optical lens.

FIG. 11 is an illustrative view of an organic layer being deposited to manufacture an organic EL display apparatus using a vapor deposition mask formed of a resin film formed in FIG. 2E.

FIG. 12 is an illustrative view showing the state in which the organic layer is formed in each of sub-pixels of R, G, B by a method of FIG. 11.

FIG. 13 is a cross-sectional view of one example of a diffraction grating formed of a resin film manufactured by the method of FIG. 1.

FIG. 14 is a conceptual view of one example of a moth-eye anti-reflection film formed of the resin film manufactured by the method of FIG. 1.

FIG. 15A is a view illustrating a problem when a resin-made film is bonded to a supporting member to form a laser-processed resin film.

FIG. 15B is a view illustrating a problem occurring when an opening is formed by laser processing in the state of FIG. 15A.

FIG. 15C is a view illustrating a problem occurring when an opening is formed by laser processing in the state of FIG. 15A.

### EMBODIMENT FOR CARRYING OUT THE INVENTION

### Embodiment 1

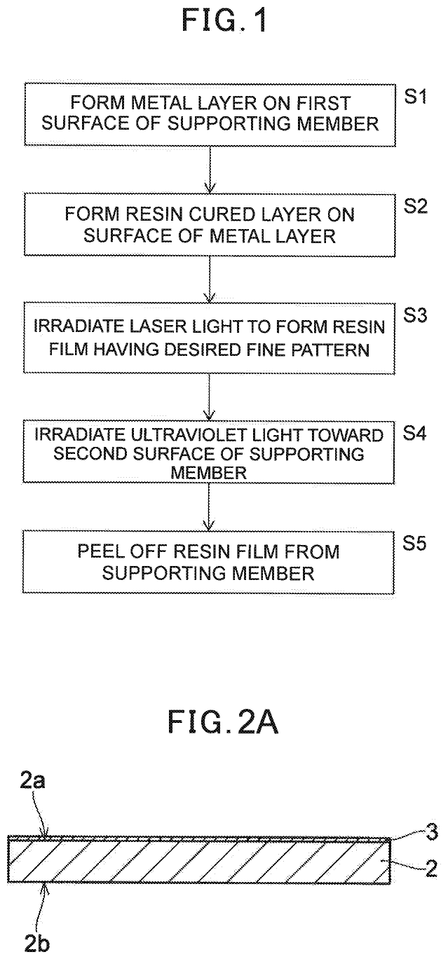

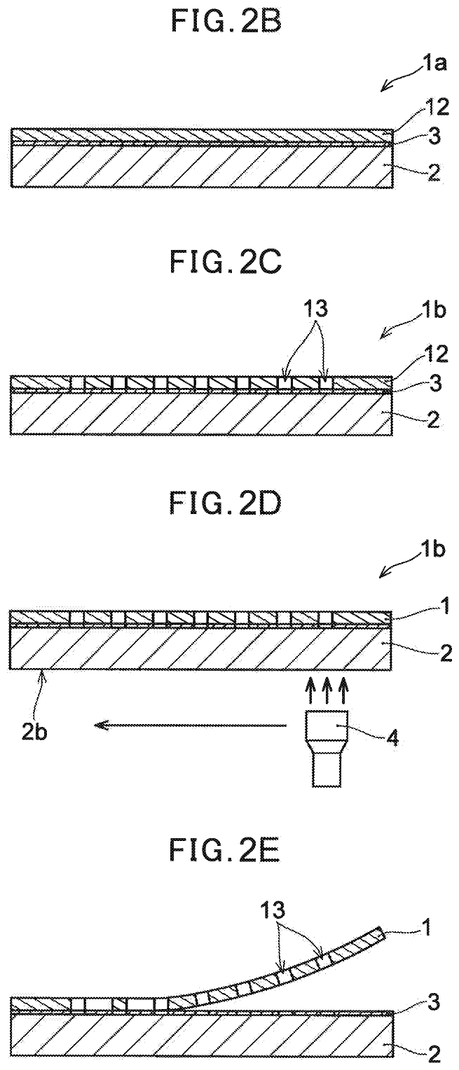

Now, with reference to the drawings, a method for manufacturing a resin film 1 having a fine pattern; a base film 1a for forming the fine pattern, which base film 1a is to form the above-mentioned resin film, and a resin film 1b with a supporting member according to a first Embodiment of the present disclosure will be described. FIG. 1 shows a flowchart showing a method for manufacturing a resin film according to a first Embodiment and FIGS. 2A to 2E show cross-sectional views of major steps, respectively.

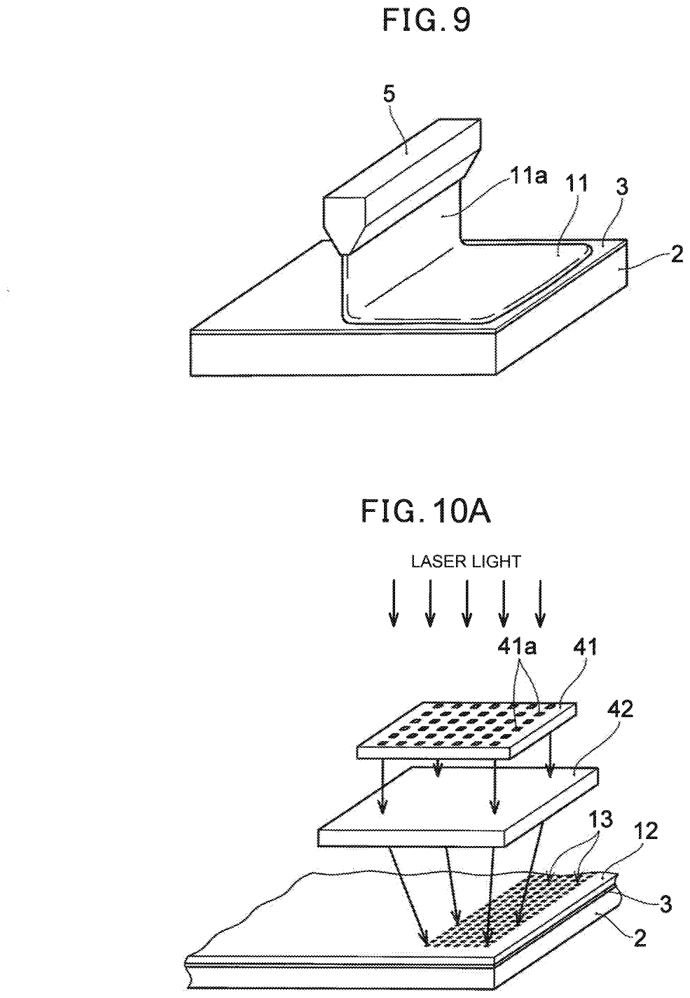

In a method for manufacturing the resin film 1 having a fine pattern according to the first Embodiment, as shown in FIG. 1 (S1), a metal layer 3 is formed on a first surface 2a of a supporting member 2 being a flat-plate (see FIG. 2A). Then, a resin cured layer 12 is formed by curing a resin coated layer 11 (see FIG. 9) being formed by coating a liquid resin material 11a (see FIG. 9) on a surface of the metal layer 3, which surface is opposite to the supporting member 2 (52). Thereafter, a laser light for fine processing is irradiated from a position opposing the resin cured layer 12 and a desired fine pattern 13 is formed on the resin cured layer 12 (S3, FIG. 2C) to provide the resin film 1 having the fine pattern. Thereafter, an ultraviolet light is irradiated toward a second surface 2b of the supporting member 2, which second surface 2b is a surface opposite to the first surface 2a, which ultraviolet light has a wavelength being different from that of the laser light for fine processing (see FIG. 2D), and the resin film 1 is peeled off from the supporting member 2 (see FIG. 2E).

In other words, varying the wavelength of the laser light for fine processing and the wavelength of the ultraviolet light to be irradiated at the time of peeling off causes much of the laser light for fine processing to be specularly reflected by the metal layer 3 to be a peeling layer to prevent an occurrence of light-heat conversion in the metal layer 3 to make forming of a fine pattern possible and makes it possible to provide the metal layer 3 with enhanced peelability by causing much of the ultraviolet light to be absorbed at the time of peeling off. Specifically, the previously-described effect can be exhibited by forming the metal layer 3 with a material having a reflectance of greater than or equal to 40%, preferably greater than or equal to 50%, and more preferably greater than or equal to 60% with respect to the wavelength of the laser light for fine processing, the laser light having transmitted through the resin cured layer 12, and an absorptance of greater than or equal to 50%, preferably greater than or equal to 60%, and more preferably greater than or equal to 70% with respect to the wavelength of the ultraviolet light having transmitted through the supporting member 2.

In other words, as a result of the present inventors having studied changes in reflectance and absorptance with respect to the wavelength using various metal layers, they have found that, while varying depending on the type of metal, with respect to the metal layer 3, there are metals having a large reflectance with respect to the wavelength of a visible light and a large absorptance with respect to the wavelength of an ultraviolet light. With respect to the above-mentioned reflectance, for any type of the metal layers 3 (thickness 0.1 μm), the reflectance of light having transmitted through a polyimide layer (absorptance: 1.89) having a 5 μm thickness as the resin cured layer 12 was calculated based on the Fresnel reflection equation. It was found that, even when the polyimide layer is etched to be gradually thinner, so that eventually no polyimide remains and a laser light is directly irradiated onto the metal layer 3, the reflectance along the way almost does not change. Moreover, also for the absorptance, the absorptance with respect to light having transmitted a glass plate with a 0.5 mm thickness as the supporting member 2 was calculated based on the Fresnel reflection equation.

### Example 1

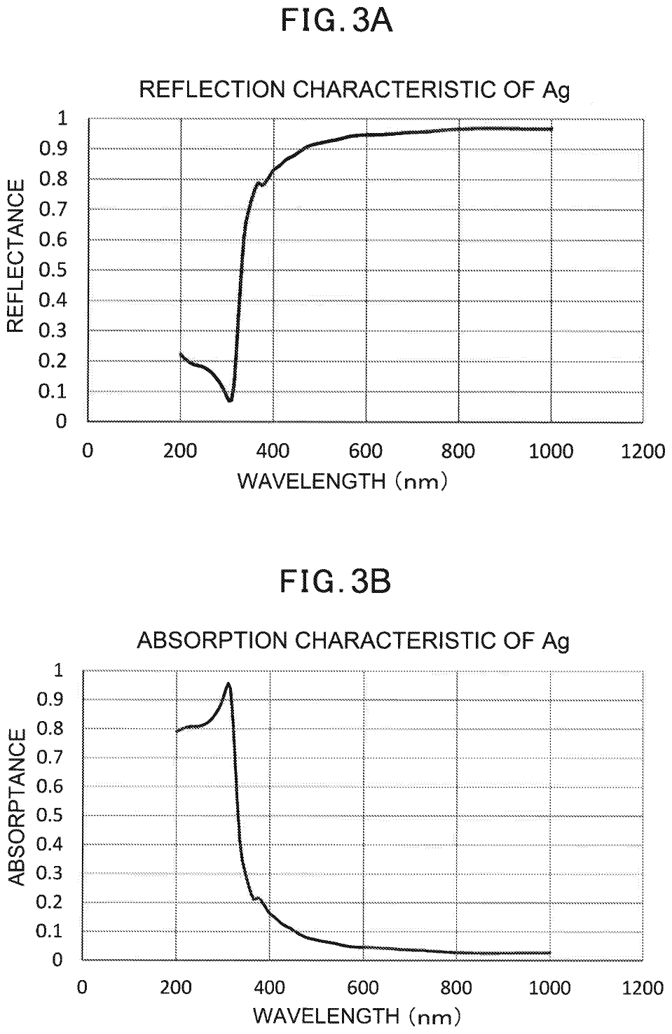

The relationships between the wavelength of laser light irradiated and each of the reflectance and the absorptance of silver (Ag) calculated in this way are shown in FIGS. 3A to 3B. As evident from FIGS. 3A to 3B, the reflectance of silver rises steeply with respect to the wavelength of greater than or equal to 300 nm and then reaches greater than or equal to 80% with respect to the wavelength of greater than or equal to 400 nm. Moreover, while the absorption characteristic of silver (Ag), as shown in FIG. 3B, is such silver (Ag) almost does not absorb a visible light with the absorption characteristic of less than or equal to 10% with respect to the visible light, silver (Ag) has, with respect to an ultraviolet light of less than or equal to the neighborhood of 300 nm, the absorption characteristic of greater than or equal to 80%. Therefore, a configuration can be realized such as having a high reflectance with respect to the wavelength at the time of fine processing and a high absorptance with respect to the wavelength at the time of peeling off, by administering fine processing with a third high harmonic wave of a YAG laser (whose wavelength is 355 nm) and irradiating an ultraviolet light of 308 nm being radiated from an excimer laser light source at the time of peeling off, for example, so that an object of the present disclosure can be achieved. Of course, a laser light of a second high harmonic wave of the YAG laser (532 nm) can also be used for fine processing. In a case of administering ultra-fine processing of less than or equal to 200 nm, it is preferable to use the ultraviolet light. In other words, the laser light at the time of fine processing such as to exceed 200 nm does not necessarily have to be the ultraviolet light, so it can have a high absorptance with respect to the wavelength of the ultraviolet light at the time of peeling off and a high reflectance with respect to the wavelength of the laser light at the time of fine processing. From the viewpoint of preventing transmittance of the laser light at the time of fine processing and increasing absorption of the ultraviolet light at the time of peeling off, the sheet thickness of silver (Ag) is preferably greater than or equal to 50 nm and less than or equal to 1 μm.

### Example 2

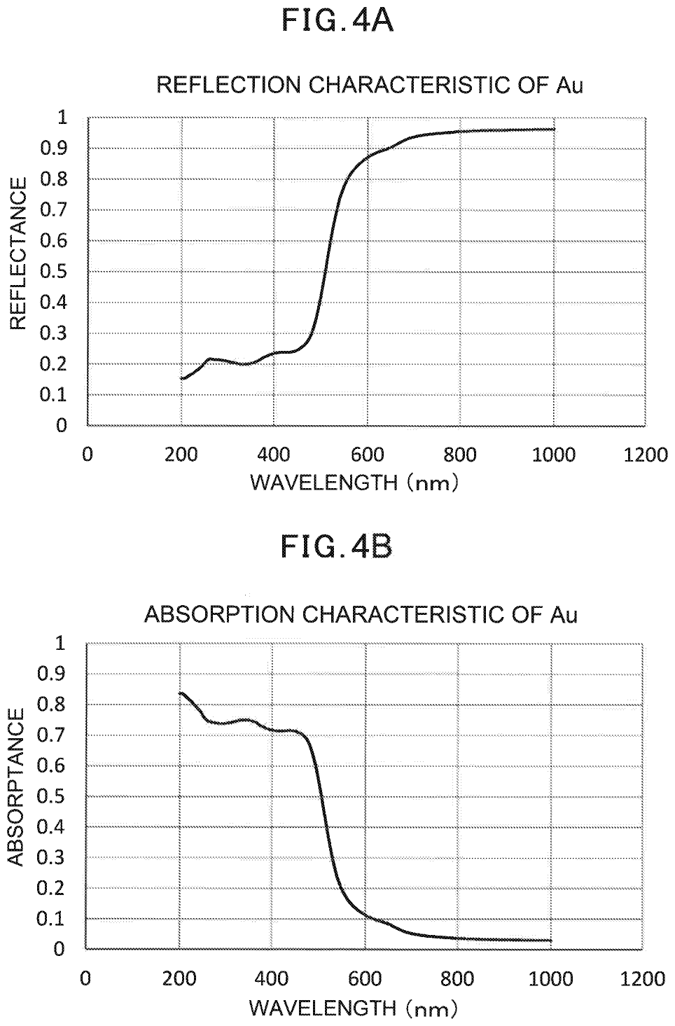

FIGS. 4A and 4B show a reflection characteristic and an absorption characteristic of gold (Au), respectively, with respect to the optical wavelength. As evident from FIG. 4A, the reflectance is approximately 40% with respect to the wavelength of approximately 500 nm, while the reflectance is close to 80% with respect to the wavelength of greater than or equal to approximately 550 nm. Therefore, using a green-color visible light (a second harmonic wave of a YAG laser: 532 nm) is preferable as a sufficient reflection is obtained and almost no light transmits through the metal layer 3. On the other hand, as evident from the absorption characteristic of FIG. 4B, the absorptance of greater than or equal to 70% is obtained with respect to the wavelength of less than or equal to 400 nm and the absorptance steeply falls with respect to the wavelength of greater than or equal to 500 nm, so that, at the time of peeling off, light of less than 500 nm, preferably an ultraviolet light of less than or equal to 400 nm, is used. An object of the present disclosure can be achieved using such combinations of wavelengths.

### Example 3

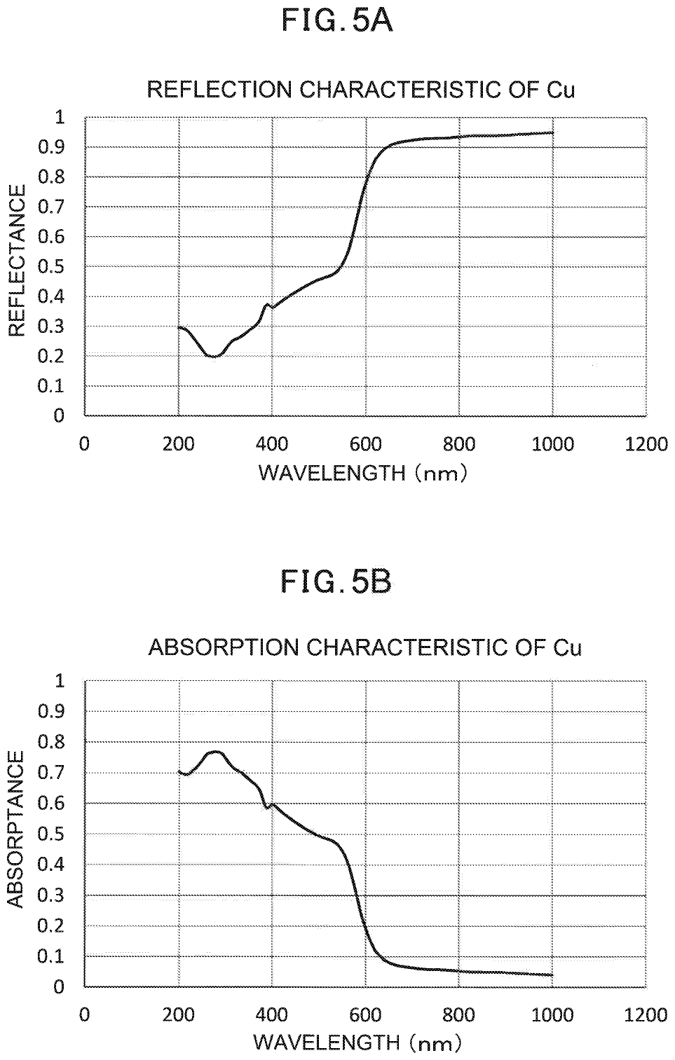

FIGS. 5A and 5B show a reflection characteristic and an absorption characteristic, respectively, of copper (Cu) with respect to the optical wavelength. As evident from FIG. 5A, while the reflectance is just over approximately 40% with respect to the wavelength of approximately 500 nm, the reflectance is close to approximately 80% with respect to the wavelength of greater than or equal to approximately 550 nm. Therefore, using a red-color light having the wavelength of around 650 nm (for example, a semiconductor laser element oscillating at 650 nm) or a near infrared light having the wavelength of around 1 μm (for example, a fundamental wave of a YAG laser: 1032 nm), a sufficient reflection is obtained and almost no light transmits through the metal layer 3. On the other hand, as evident from the absorption characteristic of FIG. 5B, the absorptance of greater than or equal to 60% is obtained with respect to the wavelength of less than or equal to 400 nm, so that, at the time of peeling off, an ultraviolet light of less than or equal to 400 nm can be used.

### Example 4

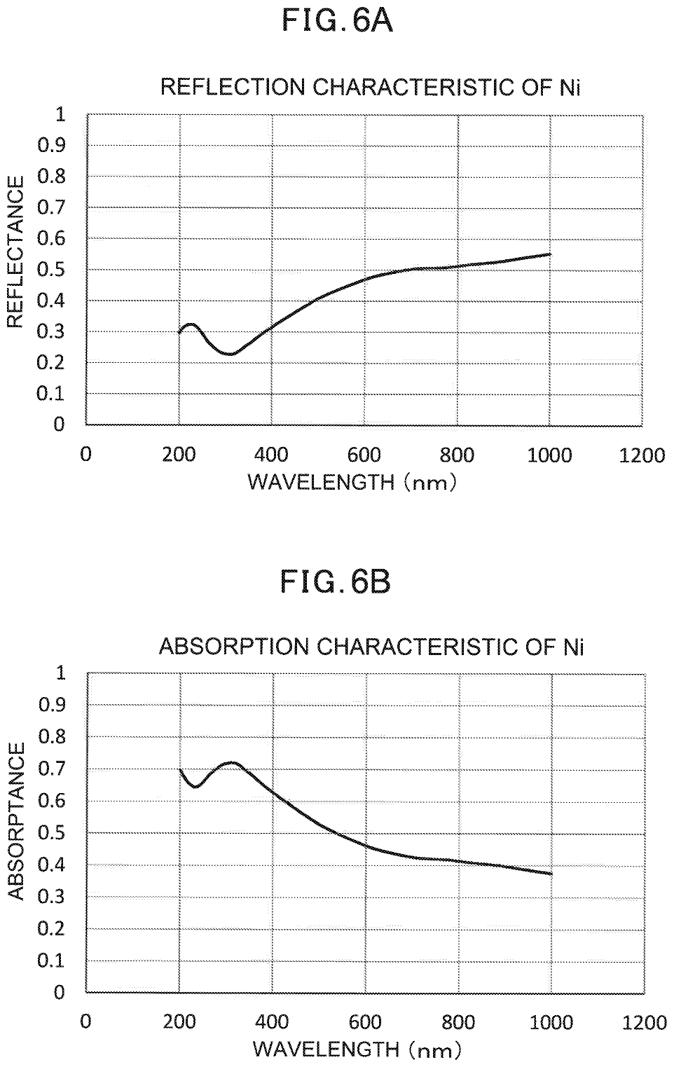

FIGS. 6A and 6B show a reflection characteristic and an absorption characteristic, respectively, of nickel (Ni) with respect to the optical wavelength. As evident from FIG. 6A, while the reflectance is somewhat low at just over approximately 43.8% with respect to light of the wavelength of 550 nm, as evident from FIG. 6B, the absorptance is greater than or equal to 55% with respect to an ultraviolet light of the wavelength of less than or equal to 400 nm, so that an object of the present disclosure can be achieved.

With respect to metals besides the above-described Examples, having differences in the reflection characteristic and the absorption characteristic according to the wavelength, which reflectance and absorptance are studied (Examples 5 and 6). The reflectance with respect to a visible light (light used for fine processing a resin film, which light is, for example, of 550 nm (a green-color light), in the neighborhood of the wavelength of a second harmonic wave of a YAG laser) and the absorptance with respect to the light of two wavelengths in the ultraviolet light range (310 nm and 360 nm, wavelengths that can be applied at the time of peeling off the resin film, which wavelengths are in the neighborhood of the wavelength of an XeCl excimer laser light and in the neighborhood of the wavelength of a third harmonic wave of a YAG laser, respectively) are summarized in Table 1, together with the previously-described Examples 1 to 4.

TABLE 1
REFLECTANCE AND ABSORPTANCE OF METAL WITH
RESPECT TO WAVELENGTH

| | | REFLECTANCE OF LIGHT | ABSORPTANCE OF LIGHT | |
|---|---|---|---|---|
| | | FOR FINE PROCESSING | FOR PEELING OFF | |
| | MATERIAL | (FOR EXAMPLE, 550 nm) | 310 nm | 360 nm |
| EXAMPLE 1 | Ag | 93.7% | 94.5% | —^{NOTE 1} |
| EXAMPLE 2 | Au | 78.5% | 75.5% | 75.7% |
| EXAMPLE 3 | Cu | 78.5% | 73.7% | 67.7% |
| EXAMPLE 4 | Ni | 43.8% | 73.4% | 68.9% |
| EXAMPLE 5 | Co | 47.4% | 61.1% | 54.3% |
| EXAMPLE 6 | Pt | 45.6% | 64.9% | 60.0% |

^{NOTE 1}:
THE ABSORPTANCE OF Ag WITH RESPECT TO 360 nm BEING 22.2% IS NOT SHOWN SINCE IT CANNOT ACHIEVE AN OBJECT OF THE PRESENT DISCLOSURE. IN THIS CASE, FOR PEELING OFF, AN ULTRAVIOLET LIGHT OF 310 nm CAN BE USED.

### Comparative Example 1

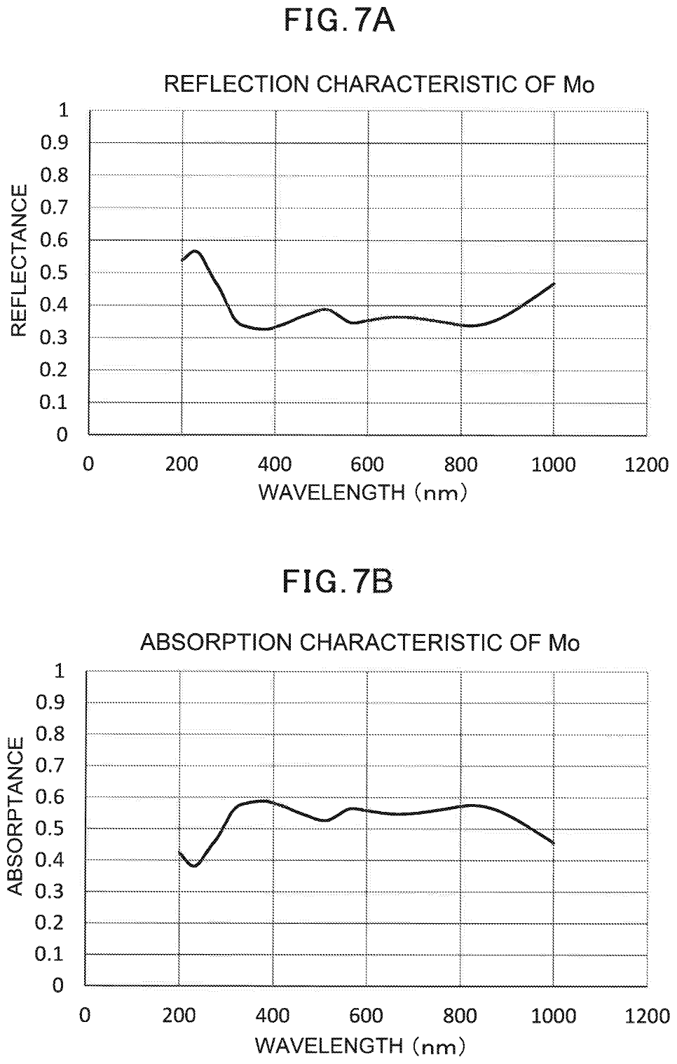

FIGS. 7A and 7B show a reflection characteristic and an absorption characteristic, respectively, of Molybdenum (Mo) with respect to the optical wavelength, as disclosed in Patent document 3. As evident from FIG. 7A, while the reflectance of approximately 50% is shown in a range in which the wavelength is low at 200 to 300 nm, the reflectance is low at below 40% with respect to the wavelength being greater or equal to 200 to 300 nm and a sufficient reflectance cannot be obtained at the time of fine processing of the resin film, so that an object of the present disclosure cannot be achieved. Moreover, as evident from FIG. 7B, while the use as an absorbing layer is possible with the absorptance of approximately 60% over a wide wavelength range, the absorbing layer does not turn out to be such a good absorbing layer.

### Comparative Example 2

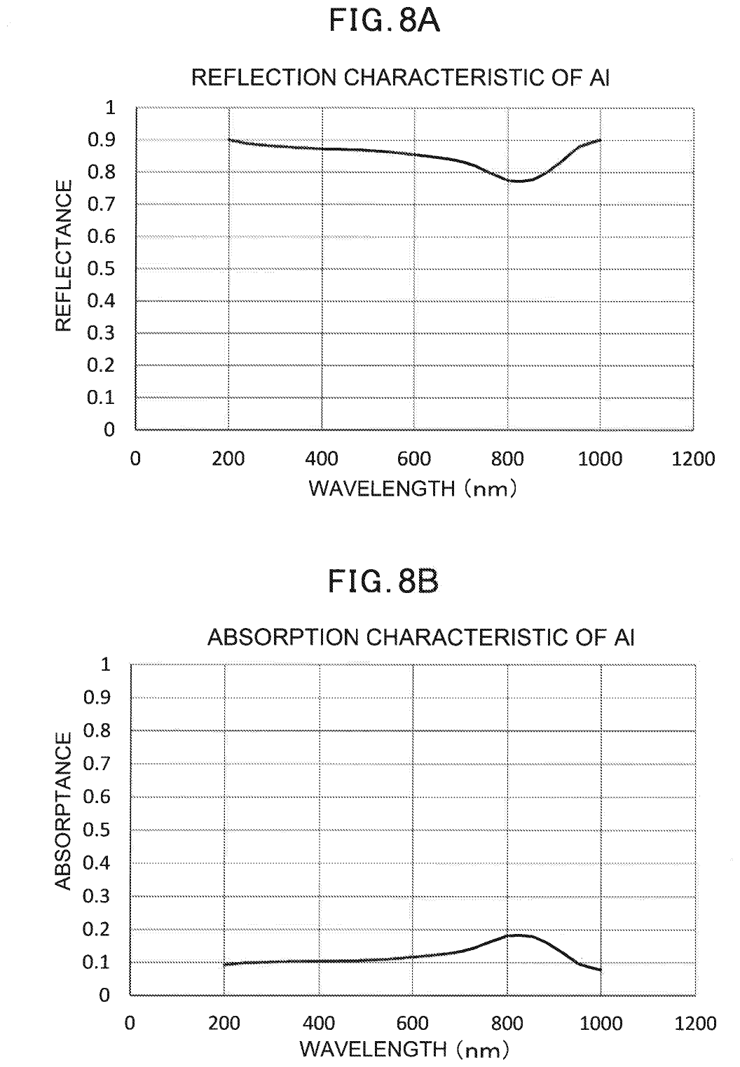

FIGS. 8A to 8B show a reflection characteristic and an absorption characteristic, respectively, of aluminum (Al) with respect to the optical wavelength. As evident from FIG. 8A, the reflectance being high at greater than or equal to 80% is shown in substantially the entire range of wavelength. However, as evident from FIG. 8B, the absorptance is low at less than or equal to 20% in substantially the entire range of wavelength, so that, in terms of absorptance, an object of the present disclosure cannot be achieved.

Besides the above Comparative Examples, there are metals that cannot achieve an object of the present disclosure with either one of the reflection characteristic and the absorption characteristic according to the wavelength. The characteristics are summarized in Table 2, together with the previously-described Comparative Examples 1 to 2, in which the reflectance with respect to a visible light (550 nm) and the absorptance with respect to two points of an ultraviolet light (310 nm and 360 nm).

TABLE 2
REFLECTANCE AND ABSORPTANCE OF METAL WITH RESPECT TO
WAVELENGTH

| | | REFLECTANCE OF LIGHT | ABSORPTANCE OF LIGHT | |
|---|---|---|---|---|
| | | FOR FINE PROCESSING | FOR PEELING OFF | |
| | MATERIAL | (FOR EXAMPLE, 550 nm) | 310 nm | 360 nm |
| COMPARATIVE | Mo | 35.6% | 54.9% | 58.6% |
| EXAMPLE 1 | | | | |
| COMPARATIVE | Al | 86.1% | 10.6% | 10.8% |
| EXAMPLE 2 | | | | |
| COMPARATIVE | Si | 13.6% | 56.1% | 56.6% |
| EXAMPLE 3 | | | | |
| COMPARATIVE | Ti | 32,0% | 69.5% | 66.6% |
| EXAMPLE 4 | | | | |
| COMPARATIVE | Cr | 34.5% | 61.9% | 60.2% |
| EXAMPLE 5 | | | | |
| COMPARATIVE | W | 26.9% | 68.5% | 64.8% |
| EXAMPLE 6 | | | | |
| COMPARATIVE | Rh | 62.5% | 33.4% | 30.4% |
| EXAMPLE 7 | | | | |

### Example 7

While each of the previously-described Examples is an Example in which the metal layer 3 is formed with a simple substance metal, the metal layer 3 can also be formed as multiple layers of a metal layer toward the resin cured layer 12 of the metal layer 3, the metal layer having a high reflectance with respect to a visible light, such as aluminum (Al) or silver (Ag), and an absorbing layer toward the supporting member 2, the absorbing layer having a high absorptance with respect to an ultraviolet light, such as titanium (Ti) or tantalum (Ta). In this case, the thickness as the reflecting layer toward the resin cured layer 12 of approximately greater than or equal to 50 nm allows a laser light to be prevented from being transmitted therethrough. Moreover, the absorbing layer toward the supporting member 2 of approximately greater than or equal to 30 nm and less than or equal to 1 μm makes it possible to be heated sufficiently. From the viewpoint of preventing an occurrence of a large stress, the total layer thickness of the metal layer having a high reflectance and the absorbing layer having a high absorptance is preferably less than or equal to approximately 1 μm. In this case, even metals listed in Table 2 in the above can be used by combining them, and, moreover, the absorbing layer does not have to be formed of a metal, so that amorphous silicon, for example, can also be used.

A method for manufacturing a resin film according to the first Embodiment of the present disclosure will be described in further detail with reference to FIG. 1 and FIGS. 2A to 2E.

On the first surface 2a of the supporting member 2 being a flat-plate (see FIG. 2A), the metal layer 3 is formed (S1). For the metal layer 3, as described previously, a metal having a high reflectance with respect to irradiation of a laser light for fine processing, and having a high absorptance with respect to irradiation of an ultraviolet light at the time of peeling off a resin film (LLO: laser liftoff) being used. Specifically, metals shown in the previously-described Examples 1 to 6, an alloy containing greater than or equal to 50 wt. % of these metals, a composite layer of these metals, or, as in the examples shown in the Example 7, a composite layer in which the surface end of the metal layer 3, in other words, a surface of the metal layer 3, which surface is opposite to the supporting member 2 and on which surface a resin coated layer is formed, is formed of a metal having a high reflectance and the end facing the supporting member 2 is formed of a metal or a non-metal material having a high absorptance with respect to an ultraviolet light, can also be used. More strictly, while, when it contains a non-metal, it will no longer be a metal layer, it has, on the surface, a metal layer having a high reflectance according to the present disclosure, so that such a composite layer is also included as the metal layer.

The thickness of the above-mentioned metal layer 3 is formed to greater than or equal to 50 nm and less than or equal to 1 μm. The thickness of greater than or equal to 50 nm allows the laser light for fine processing to be prevented from transmitting therethrough and, moreover, makes it possible to absorb the ultraviolet light to cause heat to be dissipated. The thickness being too great causes the problem of stress to occur as described previously and also causes a cost increase. In addition, it becomes difficult for a temperature increase due to the ultraviolet light to reach the interface with the resin layer and is made not possible to make deviation between the resin cured layer 12 and the metal layer 3 noticeable. Moreover, while the metal layer 3 can be formed with a method such as sputtering, vacuum vapor deposition, or the like, a metal foil having the previously-described thickness can also be bonded. While the resin sheet has no rigidity, so that air bubbles can be caught therein when it is bonded to the supporting member, the metal foil has rigidity to some extent, so that it is unlikely to catch fine air bubbles therein. Moreover, even when the air bubbles are caught therein, as long as the resin cured layer 12 is in close contact with the metal layer 3, the laser light at the time of fine processing is reflected by the metal layer, so that the fine air bubbles never make a detrimental effect on fine processing. However, it being formed by previously-described sputtering or the like is preferable since it is formed while maintaining the planar surface of the supporting member 2.

The supporting member 2 is to be made a substrate to be cured with a resin material being coated thereon, and is formed with a surface thereon, which surface has no undesired concave-convexities, and of a material that can resist the curing temperature (200 to 500° C., while it can vary with the material). This is because, when the surface has undesired concave-convexities, the concave-convexities are transferred also to the metal layer 3 to be formed thereon and unexpected concave-convexities are formed on a mask in a case of it being formed as the mask such as a vapor deposition mask, for example. In a case that, finally the resin film 1 is formed to be a vapor deposition mask, the supporting member 2 is preferably formed of a material having a small difference in linear expansion coefficient with respect to a substrate used as the vapor deposition mask (for example, a substrate of an organic EL display apparatus).

As the supporting member 2, glass is typically used. The reason is that it can resist the curing temperature of the resin film 1, 400 to 500° C. in case of polyimide, and that glass is often used for a substrate of an organic EL display apparatus, which substrate is used together with a vapor deposition mask, when depositing an organic material. However, the material for the supporting member 2 is not limited to glass, so that a sapphire or a GaN-based semiconductor or the like can be used.

Then, the resin coated layer 11 is formed by coating the liquid resin material 11a (see FIG. 9a) on a surface of the metal layer 3, which surface is opposite to the supporting member 2, and the resin cured layer 12 is formed by curing the formed resin coated layer 11 by heating it (S2, FIG. 2B). As a result, the base film 1a for forming a fine pattern being a third Embodiment of the present disclosure is obtained. It is preferable to coat a coupling agent onto a surface of the metal layer 3 prior to coating the liquid resin material 11a since it causes the resin film 1 to be easily peeled off at the time of LLO to be described below. The reason for forming the resin cured layer 12 by coating and curing of the liquid resin material 11a made of polyimide, for example, for forming the resin film is follows:

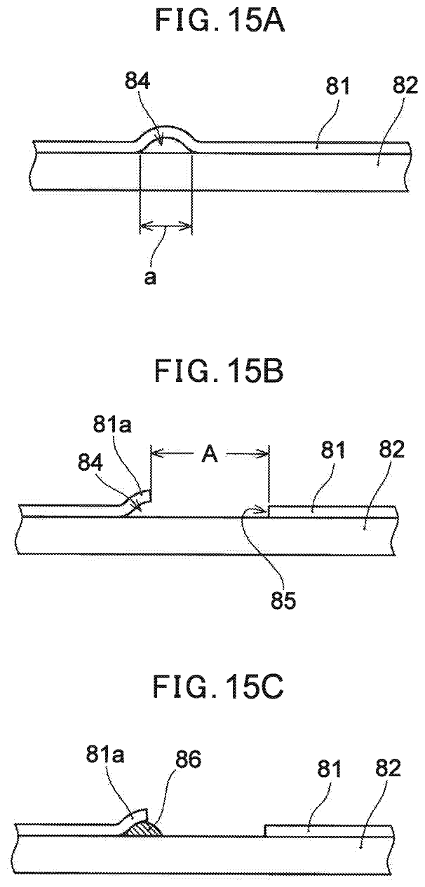

For example, as shown in FIG. 15A, when a resin sheet 81 is bonded to a supporting member 82, even when it is bonded while intervening a liquid layer such as alcohol between the resin sheet 81 and the support member 82, as shown in FIG. 15A, an air bubble 84 can be caught, which air bubble 84 has a length “a” of several μm to several ten μm or of less than or equal to submicrons (several hundred nm) that is difficult to discriminate even with a microscope, and the air bubble 84 causes burrs or processed dust.

That is, even in the air bubble 84 having such a length “a” of less than or equal to approximately several μm, as shown in FIG. 15B, when a pattern of an opening 85 is formed in a portion of the above-mentioned air bubble 84 (“A” denotes the width (approximately 60 μm) of the opening 85), the resin sheet 81 may be disconnect at a portion of the air bubble 84. As a result, as shown in FIG. 15B, in the resin sheet 81 after forming of the pattern, a bulging portion (floating portion) 81a can be formed at the portion of the air bubble 84 formed, or, as shown in FIG. 15C, processed dust 86 can get inside the above-mentioned bulging portion 81a and can merge with the resin sheet 81 to reduce the size of the opening 85, or, although not shown, a portion being floated by the air bubble can hang downward to reduce the size of the opening. While the size of such an air bubble 84 is, as described previously, in the order of less than or equal to several hundred nm for a smaller one and is normally overlooked, even the above-mentioned small air bubble 84 being caught makes a detrimental effect.

When such bulging portion 81a is formed in the resin sheet 81 or the processed dust 86 adheres thereto, display quality deteriorates when an organic EL display apparatus is formed using a vapor deposition mask formed from the above-mentioned resin sheet. The reason is that an organic layer of each of sub-pixels formed through such an opening is not formed into an accurate shape.

Then, in the present Embodiment, the resin cured layer 12 is formed by coating the liquid resin material 11a to cure the coated liquid resin material 11a rather than bonding a resin sheet thereto. While any method can be used for a method of coating the liquid resin material 11a as long as it is a method that allows layer thickness control, for example, as shown in FIG. 9, coating can be carried out using a slit coating method. That is, coating is carried out by successively moving a slot die 5 while causing the liquid resin material 11a to be discharged in a belt shape from the tip of the slot die 5 while supplying the liquid resin material 11a to the slot die 5. Even when the discharging amount of the liquid resin material 11a is not perfectly uniform, the surface will be a uniform planarizing surface after elapsing of several minutes. Then, no air bubbles of greater than or equal to 100 nm is formed at all in an interface with the metal layer 3, the resin coated layer 11 being in close contact with the metal layer 3 is formed at least across the entire surface of a region of the fine pattern being formed. Heating the above-mentioned resin coated layer 11 to approximately 200 to 500° C. can cause it to be cured. Coating of the above-mentioned liquid resin material 11a can be carried out by not necessarily slit coating, but by other methods such as spin coating, for example. While spin coating is unsuitable in terms of usage efficiency of the material in a case that a large resin film is formed, the resin coated layer 11 whose surface is planar is obtained with a thickness of approximately 3 to 15 μm, which resin coated layer 11 is in close contact with the metal layer 3.

The above-mentioned heating is carried out by heating the entirety in an oven, rather than heating the supporting member 2, for example. However, heating can be carried out from the rear surface end of the supporting member 2. The temperature profile at the time of the above-mentioned heating can be changed according to an object as described below.

When the above-mentioned resin coated layer 11 is heated, an air bubble being caught therein must surely be prevented. As described previously, the resin coated layer 11 is formed by the liquid resin material 11a being coated thereon, so that an air bubble being caught therein hardly occurs. However, when the liquid resin material 11a is coated on the metal layer 3, an air bubble can be caught therein. Therefore, in an early phase of heating for curing, the temperature of less than or equal to 100° C. is preferably maintained for approximately 10 to 60 minutes. Heating for a long time at a low temperature is preferable in that an air bubble caught in the resin coated layer 11 is released from the surface of the resin coated layer 11. At less than or equal to 100° C., no curing occurs, but rather liquidity increases and an air bubble being caught therein also expands, so that an air bubble tends to escape from the surface of the resin coated layer 11 of less than or equal to approximately 10 μm. Moreover, the temperature does not necessarily increase uniformly across the entire surface when the temperature increases due to curing. In view thereof, sufficient time being secured in an early phase of temperature increase is preferable since it causes the distribution of the temperature of the resin coated layer 11 to be uniform.

Moreover, in a case that polyimide is used as the liquid resin material 11a for a vapor deposition mask for an organic EL display apparatus, a linear expansion coefficient changes in accordance with heating conditions. Therefore, heating can be carried out with conditions such as to approach the linear expansion coefficient of the substrate for the organic EL display apparatus or of the supporting member 2 in accordance with the above-described heating conditions. For example, while heating to approximately 450° C. can be carried out in a case of polyimide, the linear expansion coefficient can be decreased by further increasing the temperature to around 500° C. to set it aside for approximately 10 to 60 minutes. Moreover, the linear expansion coefficient can be decreased also by carrying out curing at approximately 400° C. and then maintaining the temperature at approximately 450° C. for additional 30 minutes or greater. Conversely, the linear expansion coefficient can be increased by carrying out baking with the profile with a large temperature increase step (a step in which temperature is increased substantially to a certain temperature, which temperature is maintained for a long time). From these viewpoints, in heating the resin coated layer 11, preferably the temperature is increased to the curing temperature while gradually increasing the temperature between 10 and 200° C. for every 5 to 120 minutes. The above-mentioned range can further be specified by a characteristic of the resin film or a resin material to be an object.

The liquid resin material 11a can be a material to absorb a laser light for fine processing as well as to make it possible to achieve various objects as described above. However, as described previously, in a case that the resin cured layer 12 is used as a vapor deposition mask, the material is preferably a material having a small difference in linear expansion coefficient from a substrate on which the vapor deposition mask is placed and from the supporting member 2 in which the resin cured layer 12 is formed via the metal layer 3. Generally, a glass plate is used as a substrate for an organic EL display apparatus, so that polyimide is preferable from that viewpoint. Polyimide is a general term for polymer resins including imide polymerization, and can be a film-like polyimide by heating polyamic acid (liquid at normal temperature) as a precursor to promote imidization reaction.

Moreover, the linear expansion coefficient being adjustable in accordance with conditions at the time of curing is particularly preferable in that it is easily matched to the linear expansion coefficient of the substrate of the organic EL display device or the supporting member 2. While the general linear expansion coefficient of polyimide is approximately 20 to 60 ppm/degree Celsius, it can be made closer to 4 ppm/degree Celsius being the linear expansion coefficient of glass depending on baking conditions. For example, the linear expansion coefficient can be decreased by carrying out heating at a higher temperature and for a longer time. Another substrate such as a resin film rather than a glass plate can also be used as the substrate for the organic EL display apparatus, a resin material to match the linear expansion coefficient of the above-mentioned substrate can also be selected, and, other than polyimide, a transparent polyimide, PEN, PET, COP, COC, PC, or the like for example, can be used.

In this way, the base film 1a for forming the fine pattern, which base film 1a is a third Embodiment of the present disclosure, is obtained by the resin cured layer 12 being formed, with a desired resin material, on the supporting member 2 via the metal layer 3. That is, the base film 1a for forming a fine pattern according to the third Embodiment of the present disclosure is the base film 1a for forming a fine pattern, in which base film 1a a fine pattern is formed by laser processing to be described below, the base film 1a comprising: the supporting member 2 being a flat-plate; the metal layer 3 formed on the first surface 2a of the supporting member 2; and the resin cured layer 12 formed on a surface of the metal layer 3, which surface is opposite to the supporting member 2, wherein the metal layer 3, as described previously, has a reflectance being greater than or equal to 40% with respect to a light having a wavelength of a visible light or any ultraviolet light and an absorptance being greater than or equal to 50% with respect to a light having a wavelength of any ultraviolet light. By purchasing the base film 1a as such, one can form, by oneself, a desired fine pattern and form a resin film having a desired fine pattern.

Thereafter, a laser light for fine processing is irradiated from a position opposing the resin cured layer 12 and a desired fine pattern is formed on the resin cured layer 12 to provide the resin film 1 having the fine pattern (S3, FIGS. 2C to 2D). The above-mentioned laser light for fine processing preferably has a high reflectance at the metal layer 3, and generally, light being a visible light or an ultraviolet light can be used therefor. According to the present Embodiment, as described previously, light having a wavelength being different from that of an ultraviolet light to irradiate when peeling off the resin film 1 is used, so that it is selected in accordance with a reflection characteristic or an absorption characteristic of the metal layer 3. The metal layer according to the present disclosure is often a metal having a good absorption characteristic with respect to an ultraviolet light and a good reflection characteristic with respect to a visible light, so that, as a laser light for fine processing, a visible light, or, in particular, a laser light of green color (532 nm) being a second high harmonic wave of a YAG laser is preferable.

However, as described previously, in a case that the metal layer 3 is silver (Ag), the reflectance with respect to greater than or equal to approximately 350 nm is high at greater than or equal to 70%, while the absorptance with respect to the wavelength of less than or equal to 320 nm reaches greater than or equal to 80%, so that, an ultraviolet light of a third high harmonic wave (343 nm or 355 nm) of a YAG laser can be used as a laser light for fine processing, while an ultraviolet light of 308 nm of an XeCl excimer laser can be used at the time of peeling off.

While the conditions of irradiation of a laser light differ depending on material and thickness of the resin cured layer 12 to be processed, and size and shape of the fine pattern 13 to be processed, generally, irradiation of the laser light is carried out under the conditions of the pulse frequency of the laser light being 1 to 60 Hz, the pulse width being 1 to 15 nanoseconds (nsec), and the energy density of the laser light for each one pulse at the irradiating surface being 0.01 to 1 J/cm².

In a case that a 60 μm square opening is formed in a matrix at an interval of approximately 60 μm, for example, to provide a vapor deposition mask at the time of vapor depositing an organic layer of an organic EL display apparatus, a laser light having a wavelength of 532 nm, or 343 nm or 355 nm (a second high harmonic wave or a third high harmonic wave of a YAG laser) is irradiated onto the resin cured layer 12 having a 5 μm thickness, which resin cured layer 12 is formed of polyimide, under the conditions of the pulse frequency of 60 Hz, the pulse width of 7 nsec, the energy density of the laser light at the irradiating surface of 0.36 J/cm² for each one pulse, and the number of shots (the number of pulses to be irradiated) of 100.

However, the laser light to be irradiated is not limited to the YAG laser. It can be a laser having a wavelength such that fine processing can be administered therewith and such that the laser can be absorbed by the resin material. Therefore, other laser light sources such as an excimer laser, a CO₂ laser, or a semiconductor laser can be used. Of course, it goes without saying that the irradiation conditions change when the laser light source changes or the resin material changes. While irradiation of 100 shots is carried out to form an opening pattern in the previously-described example, with approximately 50 shots, a hole can be opened in a polyimide layer having a 5 μm thickness. Therefore, in a case that a concave groove such as the below-described diffraction grating is to be formed, the irradiation conditions are adjusted so as to form a clean concave groove having a predetermined depth with a little weaker output.

The laser light to be irradiated for fine processing described previously transmits through the resin cured layer 12, and is reflected by the metal layer 3 being arranged on the rear surface of the resin cured layer 12, or, in other words, between the resin cured layer 12 and the supporting member 2, again heating an opening portion of the resin cured layer 12. However, it does not transmit through the metal layer 3, so that the resin cured layer 12 is never heated again by a stray light travelling toward the supporting member 2 to be reflected by a metal such as a stage not shown, the metal being external to the supporting member 2, to return thereto. As a result, a pattern having an extremely high definition is formed. According to the present embodiment, the reason that a fine pattern is not harmed by a reflected light is described below:

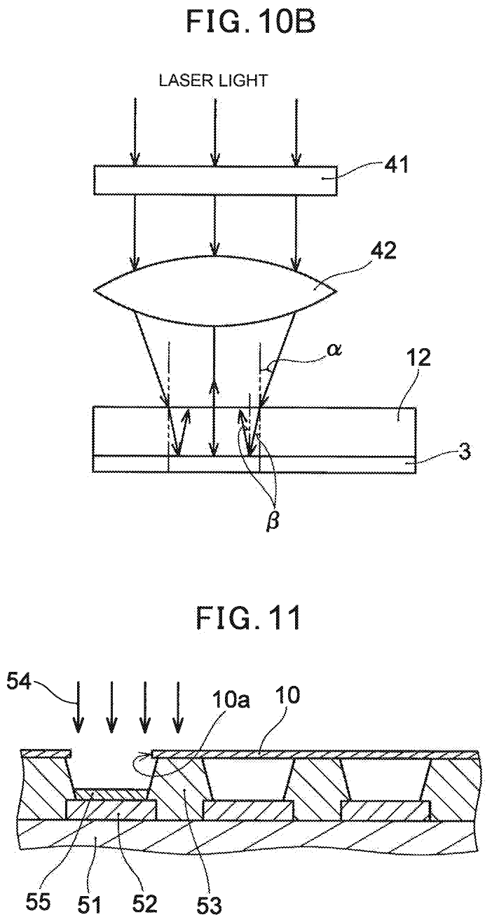

With respect to irradiation of this laser light, as shown in FIG. 10A, for example, a laser light is irradiated via a mask 41 formed of a metal plate on which a desired pattern 41a is formed, and an optical lens 42. While the lens 42 is not necessarily required, it is effective in gaining the irradiation energy density of the processing surface. In this case, the optical lens 42 is arranged at the downstream end (at the resin cured layer 12 end) in the traveling direction of the laser light with respect to the mask 41 for laser and condenses the laser light. For example, while the energy density is 100 times as large in a case that the optical lens 42 having a magnification of 10× is used, one side of the transferred pattern of the mask 41 for laser is scaled to one tenth. With the above-described irradiation of laser light, a laser light having transmitted through the opening pattern 41a of the mask 41 for laser causes a portion of the resin cured layer 12 to sublime (disappear). As a result, in alignment with a pattern of the opening portion 41a of the mask 41 for laser, onto which mask 41 a laser light is irradiated, the fine pattern 13 as a pattern being the same as the above-mentioned pattern or the pattern of the opening being reduced is formed on the resin cured layer 12. In FIG. 10A, letters 2, 3, 12, 13 refer to the same portions as the letters in FIG. 2C.

As described previously, when the optical lens 42 having a magnification of 10× is used, as shown in FIG. 10B, a parallel light from the laser light source passes through the optical lens 42 (a convex lens) through the mask 41 for laser and is contracted to one tenth on the resin cured layer 12 to be irradiated thereon. While light at the center of the above-mentioned laser light is incident onto the resin cured layer 12 in a substantially vertical manner (with the incident angle being substantially zero), the endmost light ray has an incident angle α up to approximately 10 degree. When polyimide (PI) is used for the resin cured layer 12, the refractive index is approximately 1.89, and a refraction angle β is smaller. Therefore, the refraction angle β is also small, so that the laser light being incident in a substantially vertical manner is reflected in a substantially vertical manner. That is, even for the outermost laser light of a laser spot, a reflection angle β at the time it transmits through the resin cured layer 12 and reflects by the metal layer 3 there below, is very small, so that it is reflected toward the center. Therefore, the reflected light of the laser light is reflected substantially toward the center. As a result, the irradiated laser light being reflected by the metal layer 3 to again impinge on a side wall of an opening formed on the resin cured layer 12 hardly occurs, preventing an occurrence of pattern non-uniformity due to a stray light seen conventionally.

By fine processing being administered in this way, the resin film 1b with the supporting member is obtained, in which resin film 1b the resin film 1 is in close contact with the supporting member 2, via the metal layer 3, on the supporting member 2 and has a fine pattern (see FIG. 2D). That is, this state represents the resin film 1b with the supporting member according to a fourth Embodiment of the present disclosure. In other words, the resin film 1b with the supporting member according to the fourth Embodiment comprises: a supporting member 2 being a flat-plate; a metal layer 3 formed on a first surface 2a of the supporting member 2; and a resin film 1 having a fine pattern, which resin film 1 is formed on a surface of the metal layer 3, which surface is opposite to the supporting member 2, wherein the metal layer 3 has a reflectance being greater than or equal to 40% with respect to a light having a wavelength of a visible light or any ultraviolet light and an absorptance being greater than or equal to 50% with respect to a light having a wavelength of any ultraviolet light.

Thereafter, an ultraviolet light is irradiated toward a second surface 2b of the supporting member 2, which second surface 2b is a surface opposite to the first surface 2a, which ultraviolet light has a wavelength being different from that of the laser light for fine processing (S4), and the resin film 1 is peeled off from the supporting member 2 (S5). The steps of irradiation of the ultraviolet light and peeling off can be carried out continuously, or an irradiated portion can be successively separated while scanning the irradiation of the ultraviolet light. For example, the resin film 1 can also be peeled off successively as shown in FIG. 2E while sliding a light source 4 in a direction of an arrow P as shown in FIG. 2D.

In a case that a vapor deposition mask is formed with the resin film 1 on which fine processing is administered, a rectangular frame not shown can be bonded to the peripheral edge of the resin film 1. Alternatively, after the step in FIG. 2C, with a frame being bonded to the peripheral edge of the above-mentioned resin film 1, peeling off from the supporting member 2 can be carried out. Bonding of the frame is to make handling easy while preventing the resin film 1 from being broken. As it is necessary to carry out bonding to the frame while applying tension to the resin film 1 with the conventional manufacturing method, rigidity to resist it is required for the frame, so that a metal plate having a thickness of 25 to 50 mm can be used. This is called the stretching step. In a case of bonding in the state in FIG. 2D, the stretching step can be omitted. Moreover, the frame is not mandatory, so that there is no need to have the frame. Thus, this frame can have some degree of mechanical strength, so that, for example, a metal plate having a thickness of approximately 1 to 20 mm, or a plastic plate can be used.

The wavelength of the ultraviolet light can be set in accordance with the absorption characteristic of the metal layer 3. In other words, according to the present Embodiment, an object is to cause the metal layer 3 to absorb the ultraviolet light to cause the metal layer 3 to dissipate heat. The metal layer 3 dissipating heat causes deviation between the resin film 1 and the metal layer 3 based on the fact that thermal expansion is different therebetween, making it easy to peel off the resin film 1. Therefore, it is necessary for the ultraviolet light to have a wavelength to be absorbed by the metal layer 3. With the metal layer 3 in previously-described Examples 2 to 6, with respect to either one of 310 nm and 360 nm, the absorptance is greater than or equal to 50%, and, as the laser light for peeling off, an ultraviolet light of a third high harmonic wave (355 nm or 343 nm) of a YAG laser or a 308 nm XeCl excimer laser can be used, for example.

In a case of silver (Ag), while the third high harmonic wave (355 nm or 343 nm) of the YAG laser is not appropriate as a peeling light since the absorptance with respect to the wavelength of 360 nm is only approximately 20%, as described previously, silver (Ag) has the absorptance of 94.5% with respect to light having the wavelength of 310 nm. On the other hand, silver (Ag) has the reflectance exceeding 90% with respect to light having the wavelength of 550 nm. Therefore, silver (Ag) is very suitable for both irradiation of an ultraviolet light at the time of administering fine processing and irradiation of an ultraviolet light at the time of peeling off (the respective wavelengths differ from each other).

As shown in FIG. 2D being previously described, irradiation of the ultraviolet light can be carried out onto the entire surface by arranging the linear laser light source 4 toward the second surface 2b of the supporting member 2 and, while irradiating from one end of the supporting member 2, scanning toward the other end thereof. However, irradiation of the laser light can be carried out onto the entire surface at one time. The intensity of the laser light is set to the degree to enable heating the metal layer 3 and is preferably set to the degree such as to prevent it from being so high as to transmit through the metal layer 3 to heat the resin film 1. From that viewpoint, it does not necessarily have to be the laser light, so it suffices to be a light source radiating a light having a short wavelength, such as a xenon lamp, a high-pressure mercury lamp, or an ultraviolet ray LED.

With respect to the resin film 1 having the fine pattern, as described previously, fine processing is administered with the resin cured layer 12 being in close contact with the supporting member 2 via the metal layer 3. Therefore, even in a case that an opening of the fine pattern is formed, an opening is hardly formed in an air bubble portion. Moreover, the laser light for fine processing is specularly reflected by the metal layer 3, therefor there is never a case of being randomly reflected, thereby to disturb the opening pattern. Furthermore, the resin film 1 can be easily peeled off from the supporting member 2.

Moreover, the laser light to be irradiated at the time of peeling off (LLO) is substantially absorbed or reflected by the metal layer 3, so that it never penetrates the metal layer to heat the resin film 1. Therefore, the debris scattering at the time of laser processing to be adhered to the surface of the resin cured layer 12 never burs on the resin film 1. As a result, the debris produced at the time of laser processing can be easily removed with cleaning.

According to the present Embodiment 1, processed dust is hardly caught, so that a fine pattern is never deformed, or burrs never occur. As a result, in a case that an organic layer is deposited using a vapor deposition mask formed of a resin film formed in this way and an organic EL display apparatus is formed, the organic EL display apparatus has been obtained, which organic EL display apparatus has no variations between pixels and has an extremely superior display quality. Moreover, even in a case of providing an optical element such as a diffraction grating, the optical element having an extremely superior characteristic has been obtained.

### Second Embodiment

Next, a method for manufacturing an organic EL display apparatus using a vapor deposition mask formed of a resin film manufactured in this way will be described. As a method for manufacturing what is other than a vapor deposition mask can be carried out by a well-known method, only a method for depositing an organic layer using a vapor deposition mask will be described.

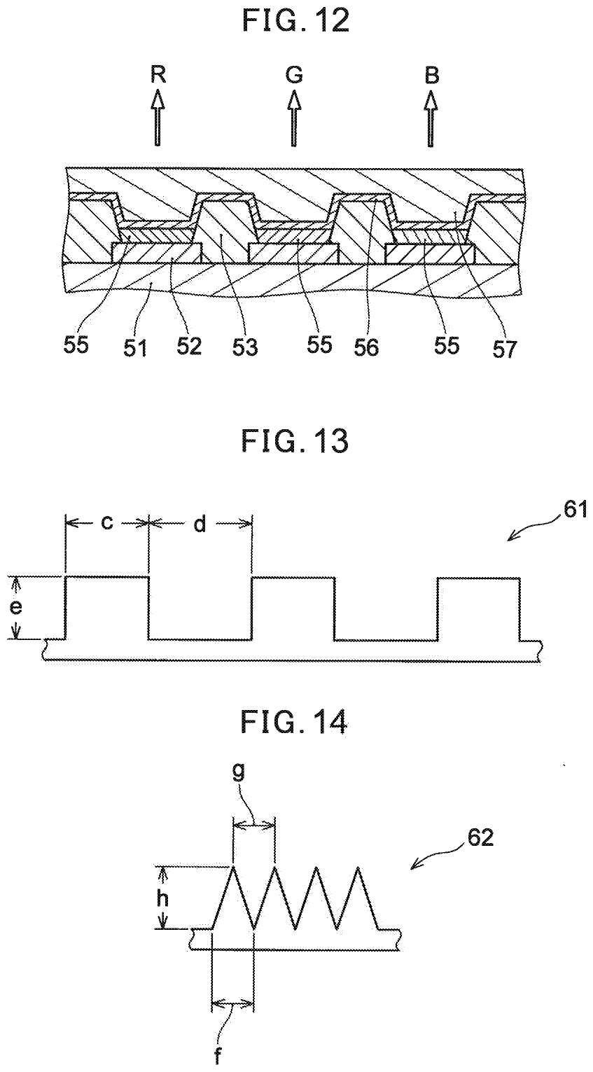

In a method for manufacturing an organic EL display apparatus according to the present invention, first, a vapor deposition mask 1 (10) is formed by forming an opening pattern (a fine pattern) 13 (see FIG. 2C) by irradiation of a laser light such as a visible light for fine processing onto a resin cured layer 12 being cured by coating a liquid resin material 11a on a metal layer 3 on a supporting member 2 described previously (see FIG. 9). Then, as shown in FIGS. 11 to 12, an organic layer 55 is deposited on a substrate (a first electrode 52), by aligning and superimposing a vapor deposition mask 10 having an opening 10a on a substrate 51 on which a first electrode 52 is formed, together with TFTs not shown, and vapor-depositing an organic material 54. After the organic layer 55 of each of sub-pixels is formed, the vapor deposition mask 10 is removed and a second electrode 56 is formed, thereby a portion of the organic layer 55 of the organic EL display apparatus is formed. While FIG. 11 shows the substrate 51 at the lower end for ease of understanding in relation to FIG. 12, practically the substrate 51 is turned upside down, so that the organic material 54 scatters from the lower end. This will be detailed further with a specific example.

While the substrate 51 is not shown, a switching element such as a TFT is formed on a glass plate, for example, for each of RGB sub-pixels of each of pixels, and a first electrode (for example, the anode) connected to the switching element is formed, on a planarizing layer, with a combination of a metal layer such as Ag or APC, and an ITO layer. As shown in FIG. 11, insulating banks 53 made of SiO₂ or the like, which insulating banks 53 shield between the sub-pixels, are formed between the sub-pixels. The previously-described vapor deposition mask 10 is aligned and fixed onto the insulating banks 53 of the substrate 51, The opening 10a of the vapor deposition mask 10 is formed to be smaller than an interval of surfaces of the insulating banks 53. The organic material being deposited on the side wall of the insulating banks 53 is suppressed as much as possible, achieving prevention of a decrease in light emitting efficiency.

In the above-described state, the organic material 54 is vapor-deposited in a vapor deposition apparatus, the organic material 54 is vapor-deposited only onto an opening portion of the vapor deposition mask 10, and the organic layer 55 is formed on the first electrode 52 of a desired sub-pixel. As described previously, the opening 10a of the vapor deposition mask 10 is formed to be smaller than the interval of the surfaces of the insulating banks 53, causing it difficult for the organic material 54 to be deposited onto the side wall of the insulating banks 53. As a result, as shown in FIGS. 11 to 12, the organic layer 55 is deposited substantially only on the first electrode 52. In the above-described vapor deposition step, the vapor deposition mask is successively changed, and the vapor deposition step is carried out for each of the sub-pixels. As described below, a vapor deposition mask can also be used, with which vapor deposition mask the same material is vapor-deposited to a plurality of sub-pixels at the same time.

While the organic layer 55 is simply shown as one layer, in FIGS. 11 and 12, practically, the organic layer 55 is formed as a deposited layer of a plurality of layers being formed of different materials. For example, as a layer being in contact with the anode 52, a hole injecting layer formed of a material having a good compatibility with ionization energy to improve the injectability of holes can be provided. A hole transport layer being capable of trapping electrons into a light emitting layer (energy barrier) as well as enhancing a stable transport of holes is formed, with an amine-based material, for example, on the hole injecting layer. Moreover, a light emitting layer to be selected according to the light emitting wavelength is formed thereon with Alq₃ being doped with a red or green organic fluorescent material with respect to the red color or the green color, for example. Furthermore, as a blue-color based material, a DSA-based organic material is used. An electron transport layer to stably transport electrons as well as to further improve the injectability of electrons is formed, with Alq₃, on the light emitting layer. The organic layer 55 is formed by depositing approximately several ten nm of each of the above-mentioned layers. An electron injecting layer of LiF or Liq to improve the injectability of electrons can also be provided between the above-mentioned organic layer and the metal electrode.

For the organic layer 55, with respect to the light emitting layer, organic layers of a material corresponding to each of colors of R, G, B are deposited. Moreover, emphasizing the light emitting performance, preferably, the hole transport layer and the electron transport layer are separately deposited with a material suitable for the light emitting layer. However, taking into account the material cost, they can also be deposited with the same material common to two or three colors of R, G, B. In a case that a material common to sub-pixels of at least two colors is deposited, a vapor deposition mask in which openings are formed is formed in common sub-pixels. In a case the vapor deposition layer differs for individual sub-pixels, for example, one vapor deposition mask 10 can be used to continuously vapor-deposit each organic layer in the R sub-pixels, for example, and, in a case that an organic layer common to R, G, B is vapor-deposited, the organic layer of each of the sub-pixels is vapor-deposited to a lower end of the above-mentioned common organic layer, and the organic layer of all of the pixels is vapor-deposited at once, at the common organic layer, using a vapor deposition mask having an opening formed in R, G, Bs.

Then, when forming of all of the organic layers 55 and the electron injecting layers such as an LiF layer are completed, the vapor deposition mask 10 is removed, and the second electrode (for example, a cathode) 56 is formed on the entire surface. The example shown in FIG. 12 is of a top-emission type in which light is emitted from the upper end, so that the second electrode 56 is made of a light-transmitting material, for example, a thin layer of Mg—Ag eutectic layer. Other ones can use Al. In a case of a bottom emission type in which light is emitted from the substrate 51 end, ITO, In₃O₄ are used for the first electrode 52, while a metal having a small work function, such as Mg, K, Li, Al, for example, can be used for the second electrode. A protecting layer 57 made of, for example, Si₃N₄, or the like is formed on a surface of the second electrode 56. The entirety thereof is sealed with a sealing layer, not shown, made of glass, a resin film, and the organic layer 55 is configured to be prevented from absorbing moisture. Moreover, the organic layer can be made common as much as possible, and can be structured to provide a color filter toward a surface thereof.

FIGS. 13 and 14 are examples in which the previously-described resin film 1 is formed as an optical element such as a diffraction grating 61 or a moth-eye anti-reflection film 62. That is, FIG. 13 is a view showing a cross section of the diffraction grating; as a width c of a convex portion and an interval d thereof are both approximately 0.3 to 1 μm and a depth e thereof is approximately 100 to 500 nm, a very fine pattern to the degree of an optical wavelength is required, so that, even when the resin film 1 has only slight undesired concave-convexities, the above-mentioned fine pattern cannot be formed accurately. This can be problematic even with an air bubble being far smaller than that in a case of the previously-mentioned vapor deposition mask; however, as described previously, the resin film 1 according to the present Embodiment is finely processed while it is being in close contact with the supporting member 2 via the metal layer 3, so that an accurate diffraction grating with no missing portion at all can be obtained. As a result, a clear diffraction image can be obtained.

Moreover, an example shown in FIG. 14 is an example of a moth-eye anti-reflection film. In this example as well, while a very fine concave-convexity having a width (bottom diameter) f of approximately 50 to 200 nm, a pitch g of approximately 50 to 300 nm, and a height h of approximately 200 to 3000 nm, for example, are formed, a precise fine structure is formed as with the previously-described diffraction grating. It is noted that, while the tip of the convex portion in FIG. 14 is drawn in a shape in which the tip of the convex portion is pointed, it can also have a round shape. Forming of such a concave-convexity using irradiation of a laser light can be obtained, for example, by a mask having a gradually varying transmittance with a large transmittance of the laser light in the central portion of the concave portion and the transmittance decreasing toward the periphery thereof.

### CONCLUSION

(1) A method for manufacturing a resin film according to a first Embodiment of the present disclosure comprises: forming a metal layer on a first surface of a supporting member being a flat-plate; forming a resin cured layer by curing a liquid resin material being applied on a surface of the metal layer, which surface is opposite to the supporting member; forming a resin film having the fine pattern by forming a desired fine pattern on the resin cured layer with irradiation of a laser light for fine processing from a position opposing the resin cured layer; irradiating an ultraviolet light toward a second surface of the supporting member, which second surface is a surface opposite to the first surface, which ultraviolet light has a wavelength being different from a wavelength of the laser light for fine processing; and peeling off the resin film from the supporting member.

According to a first Embodiment of the present disclosure, a laser light for fine processing being irradiated onto a resin cured layer being a liquid resin material cured on a surface of a metal layer to administer fine processing makes it possible to specularly reflect the laser light having transmitted through the resin cured layer, so that the laser light is never being reflected irregularly to return to the resin cured layer. As a result, the fine pattern is never disturbed, and, moreover, it never occurs that the irradiated laser light is converted to heat by the metal layer to expand the metal layer and distort the resin film, so that a very accurate fine pattern is obtained. Moreover, when the resin film is peeled off from the supporting member, it is peeled off after irradiating, from a second surface of the supporting member, an ultraviolet light having a wavelength different from that of a laser light for fine processing, the contactability between the metal layer and the resin film can be decreased, making it possible to easily peel off the resin film. As a result, the fine pattern is never deformed.

(2) The metal layer is preferably made of a material having a reflectance of greater than or equal to 40% with respect to a wavelength of the laser light for fine processing, the laser light having transmitted through the resin cured layer, and an absorptance of greater than or equal to 50% with respect to a wavelength of the ultraviolet light having transmitted through the supporting member. In this way, the laser light for fine processing is specularly reflected in a sure manner by the metal layer, eliminating re-processing of the resin cured layer by a stray light having transmitted thorough the supporting member. Moreover, the irradiated laser light being converted to heat by the metal layer to expand the metal layer and distort the resin film never occurs, so that an accurate fine pattern is obtained. Furthermore, the metal layer absorbs the irradiated ultraviolet light to cause the temperature to increase when the resin film is peeled off, so that the resin film and the metal layer can be easily separated because of the difference in thermal expansion between the resin film and the metal layer.

(3) Specifically, preferably, the laser light for fine processing has a wavelength of greater than or equal to 340 nm and less than or equal to 700 nm, and the ultraviolet light has a wavelength of greater than or equal to 250 nm and less than or equal to 380 nm.

(4) More specifically, preferably, the laser light for fine processing comprises a second high harmonic wave of a YAG laser and the ultraviolet light comprises a third high harmonic wave of the YAG laser.

(5) The metal layer can be selected from at least one selected from a group of silver, gold, copper, cobalt, nickel, platinum, and an alloy containing greater than or equal to 50 wt. % of these metals, and titanium nitride.

(6) Even in a case that the laser light for fine processing comprises a third high harmonic wave of a YAG laser (the light being an ultraviolet light), the ultraviolet light comprises a wavelength of 308 nm, and the metal layer is made of silver, a very good reflection characteristic of the laser light for fine processing as well as a very good reflection characteristic of the ultraviolet light are obtained. In other words, the laser light for fine processing is not limited to a visible light and can be a light having a wavelength being different from that of the ultraviolet light at the time of peeling off.

(7) Air bubbles contained in the liquid resin material can be removed prior to curing the liquid resin material to suppress floating, and adhering of foreign substance in a finely processed portion of the resin film.

(8) The metal layer can be formed by at least one of sputtering, vacuum vapor deposition, laser ablation, and CVD to obtain a planar metal layer on a surface, which planar metal layer has no concave-convexities. As a result, fine processing can be administered even at the time of processing of the resin cured layer.

(9) The supporting member being formed of a glass plate is preferable since an ultraviolet light at the time of peeling off a resin film is transmitted therethrough to easily irradiate onto a metal layer and even the resin film being made to be a vapor deposition mask is close in thermal expansion to a substrate used in vapor deposition of an organic EL display apparatus.

(10) The liquid resin material being a polyimide is preferable in that it can resist a high temperature of approximately 500 degree Celsius and in that it can be close in thermal expansion coefficient with respect to a substrate of an organic EL display apparatus.

(11) A processing by the irradiation of the laser light being a formation processing of the fine pattern to form an optical element having a fine pattern makes it possible to obtain the optical element of the fine pattern.

(12) A processing by the irradiation of the laser light can also be applied to a processing to form a vapor deposition mask to vapor deposit an organic material for each of pixels on a substrate.

(13) A method for manufacturing an organic EL display apparatus according to a second Embodiment of the present disclosure, in which an organic layer is deposited on a substrate to manufacture the organic EL display apparatus, which method comprises: forming a vapor deposition mask with the method according to the above-mentioned (12) in the above; aligning and superimposing the vapor deposition mask on a substrate with a first electrode, and depositing the organic layer on the substrate by vapor-depositing an organic material; and removing the vapor deposition mask and forming a second electrode.

According to the second Embodiment of the present disclosure, a vapor deposition mask of an accurate pattern is obtained, so that an organic EL display apparatus having no variations in each pixel of the organic EL display apparatus formed using the above-mentioned vapor deposition mask and being extremely superior in display quality is obtained.

(14) A base film for forming a fine pattern according to a third Embodiment of the present disclosure, in which base film, the fine pattern is to be formed by laser processing, the base film comprising: a supporting member being a flat-plate; a metal layer formed on a first surface of the supporting member; and a resin cured layer formed on a surface of the metal layer, which surface is opposite to the supporting member, wherein the metal layer has a reflectance being greater than or equal to 40% with respect to a light having a wavelength of a visible light or any wavelength of an ultraviolet light and an absorptance being greater than or equal to 50% with respect to a light having any wavelength of an ultraviolet light.

According to the third Embodiment of the present disclosure, the above-mentioned base film can be purchased to form a desired fine pattern, to widen the practical range.

(15) A resin film with a supporting member according to a fourth Embodiment of the present disclosure comprises: a supporting member being a flat-plate; a metal layer formed on a first surface of the supporting member; and a resin film having a fine pattern, which resin film is formed on a surface of the metal layer, which surface is opposite to the supporting member, wherein the metal layer has a reflectance being greater than or equal to 40% with respect to a light having a wavelength of a visible light or any wavelength of an ultraviolet light and an absorptance being greater than or equal to 50% with respect to a light having any wavelength of an ultraviolet light.

According to the fourth Embodiment of the present disclosure, the resin film on which a desired fine pattern is formed can be obtained while it is adhered to the supporting member, making it possible to obtain a resin film whose storage is easy, the resin film having a fine pattern merely by irradiating an ultraviolet light at the time of use.

### EXPLANATION OF REFERENCE NUMERALS

1 Resin film
1a Base film for forming fine pattern
1b Resin film with supporting Member
2 Supporting member
3 Metal layer
10 Vapor deposition mask
12 Resin cured layer
13 Fine pattern
51 Substrate
52 First electrode
53 Insulating bank
54 Organic material
55 Organic layer
56 Second electrode
57 Protecting layer
61 Diffraction grating
62 Anti-reflection layer

1. A method for manufacturing a resin film having a fine pattern, the method comprising:
forming a metal layer on a first surface of a supporting member being a flat-plate;
forming a resin cured layer by curing a liquid resin material being applied on a surface of the metal layer, which surface is opposite to the supporting member;
forming a resin film having the fine pattern by forming a desired fine pattern on the resin cured layer with irradiation of a laser light for fine processing from a position opposing the resin cured layer;
irradiating an ultraviolet light toward a second surface of the supporting member, which second surface is a surface opposite to the first surface, which ultraviolet light has a wavelength being different from a wavelength of the laser light for fine processing; and
peeling off the resin film from the supporting member,
wherein the metal layer is made of a material having a reflectance of greater than or equal to 40% with respect to a wavelength of the laser light for fine processing, the laser light having transmitted through the resin cured layer, and an absorptance of greater than or equal to 50% with respect to a wavelength of the ultraviolet light having transmitted through the supporting member.

2. (canceled)

3. The method for manufacturing a resin film having a fine pattern according to claim 1,
wherein the laser light for fine processing has a wavelength of greater than or equal to 340 nm and less than or equal to 700 nm, and the ultraviolet light has a wavelength of greater than or equal to 250 nm and less than or equal to 380 nm.

4. The method for manufacturing a resin film having a fine pattern according to claim 1,
wherein the laser light for fine processing comprises a second high harmonic wave of a YAG laser and the ultraviolet light comprises a third high harmonic wave of the YAG laser.

5. The method for manufacturing a resin film having a fine pattern according to claim 1,
wherein the metal layer is made of at least one selected from a group of silver, gold, copper, cobalt, nickel, platinum, an alloy containing greater than or equal to 50 wt. % of these metals, and titanium nitride.

6. The method for manufacturing a resin film having a fine pattern according to claim 1,
wherein the laser light for fine processing comprises a third high harmonic wave of a YAG laser, the ultraviolet light comprises a wavelength of 308 nm, and the metal layer is made of silver.

7. The method for manufacturing a resin film having a fine pattern according to claim 1,
wherein air bubbles contained in the liquid resin material are removed prior to curing the liquid resin material.

8. The method for manufacturing a resin film having a fine pattern according to claim 1,
wherein the metal layer is formed by at least one of sputtering, vacuum vapor deposition, laser ablation, and CVD.

9. The method for manufacturing a resin film having a fine pattern according to claim 1,
wherein the supporting member is formed of a glass plate.

10. The method for manufacturing a resin film having a fine pattern according to claim 1,
wherein the liquid resin material is a polyimide.

11. The method for manufacturing a resin film having a fine pattern according to claim 1,
wherein a processing by the irradiation of the laser light is a formation processing of the fine pattern to form an optical element having a fine pattern.

12. The method for manufacturing a resin film having a fine pattern according to claim 1,
wherein a processing by the irradiation of the laser light is a processing to form a vapor deposition mask to vapor-deposit an organic material for each of pixels on a substrate.

13. A method for manufacturing an organic electroluminescent (EL) display apparatus in which an organic layer is deposited on a substrate, the method comprising:
forming a vapor deposition mask with the method according to claim 12;
aligning and superimposing the vapor deposition mask on a substrate with a first electrode, and depositing the organic layer on the substrate by vapor-depositing an organic material; and
removing the vapor deposition mask and forming a second electrode.

14. A base film for forming a fine pattern, in which base film, the fine pattern is to be formed by laser processing, the base film comprising:
a supporting member being a flat-plate;
a metal layer formed on a first surface of the supporting member; and
a resin cured layer formed on a surface of the metal layer, which surface is opposite to the supporting member,
wherein the metal layer has a reflectance being greater than or equal to 40% with respect to a light having a wavelength of a visible light or any wavelength of an ultraviolet light and an absorptance being greater than or equal to 50% with respect to a light having any wavelength of an ultraviolet light.

15. A resin film with a supporting member, the resin film comprising:
a supporting member being a flat-plate;
a metal layer formed on a first surface of the supporting member; and
a resin film having a fine pattern, which resin film is formed on a surface of the metal layer, which surface is opposite to the supporting member,
wherein the metal layer has a reflectance being greater than or equal to 40% with respect to a light having a wavelength of a visible light or any wavelength of an ultraviolet light and an absorptance being greater than or equal to 50% with respect to a light having any wavelength of an ultraviolet light.

16. A base film for forming a fine pattern, in which base film, the fine pattern is to be formed by laser processing, the base film comprising:
a supporting member being a flat-plate;
a metal layer formed on a first surface of the supporting member; and
a resin cured layer formed on a surface of the metal layer, which surface is opposite to the supporting member,
wherein in the metal layer, a reflectance with respect to any wavelength of a visual light is greater than a reflectance with respect to any wavelength of an ultraviolet light, and an absorptance with respect to the any wavelength of the ultraviolet light is greater than 60% and is greater than an absorptance with respect to the any wavelength of the visual light.

17. A resin film with a supporting member, the resin film comprising:
a supporting member being a flat-plate;
a metal layer formed on a first surface of the supporting member; and
a resin film having a fine pattern, which resin film is formed on a surface of the metal layer, which surface is opposite to the supporting member,
wherein in the metal layer, a reflectance with respect to any wavelength of a visual light is greater than a reflectance with respect to any wavelength of an ultraviolet light, and an absorptance with respect to the any wavelength of the ultraviolet light is greater than 60% and is greater than an absorptance with respect to the any wavelength of the visual light.
